(19) United States
(12) Patent Application Publication
(10) Pub. No.: US 2026/0096231 A1
(43) Pub. Date: Apr. 2, 2026

(54) IMAGE SENSOR

(71) Applicant: SAMSUNG ELECTRONICS CO., LTD., Suwon-si (KR)

(72) Inventors: Wook LEE, Suwon-si (KR); Changhyo KOO, Suwon-si (KR); Jaeho KIM, Suwon-si (KR); Yonghee PARK, Suwon-si (KR); Irfan SHABBIR, Suwon-si (KR)

(73) Assignee: SAMSUNG ELECTRONICS CO., LTD., Suwon-si (KR)

(21) Appl. No.: 19/084,335

(22) Filed: Mar. 19, 2025

(30) Foreign Application Priority Data
Sep. 30, 2024 (KR) 10-2024-0132819

(51) Int. Cl. H10F 39/00; H04N 25/77

(52) U.S. Cl. CPC H10F 39/80373; H10F 39/8023; H10F 39/8063; H10F 39/807; H10F 39/811; H04N 25/77

(57) ABSTRACT

An image sensor includes a substrate having a first surface and a second surface opposing the first surface, a first isolation pattern defining a plurality of shared pixel regions in the substrate, and a plurality of shared pixels respectively in the plurality of shared pixel regions. Each of the plurality of shared pixels includes a second isolation pattern defining a plurality of unit pixel regions in a corresponding shared pixel region, the second isolation pattern having an open region in a plan view, a plurality of photodiodes in the plurality of unit pixel regions, respectively, a plurality of floating diffusion regions in the plurality of unit pixel regions, and an inter-pixel overflow (IPO) gate overlapping the open region in the plan view. Each of the plurality of floating diffusion regions in each of the plurality of shared pixels is spaced apart from the IPO gate.

### CROSS-REFERENCE TO RELATED APPLICATION

This application is based on and claims priority to Korean Patent Application No. 10-2024-0132819, filed on Sep. 30, 2024, in the Korean Intellectual Property Office, the disclosure of which is incorporated herein by reference in its entirety.

### BACKGROUND

One or more example embodiments of the disclosure relate to an image sensor.

An image sensor may include a plurality of unit pixels arranged in a two-dimensional array structure. In general, a unit pixel may include a single photodiode and a plurality of pixel transistors. Here, the pixel transistors may include, for example, a transfer transistor, a reset transistor, a source follower transistor, and a selection transistor.

As a pixel size decreases, a shared pixel structure in which a plurality of pixels share a pixel transistor has been used for an image sensor. For example, when several pixels share pixel transistors, the number of pixel transistors per unit pixel may decrease and an actual area of a photodiode may increase.

### SUMMARY

One or more example embodiments of the disclosure provide an image sensor capable of electronically controlling an inter-pixel overflow (IPO) barrier potential level between a plurality of photodiodes included in a pixel group.

According to an aspect of an example embodiment of the disclosure, there is provided an image sensor including: a substrate having a first surface and a second surface opposing the first surface, a first isolation pattern defining a plurality of shared pixel regions in the substrate, and a plurality of shared pixels respectively in the plurality of shared pixel regions. Each of the plurality of shared pixels may include a second isolation pattern defining a plurality of unit pixel regions in a corresponding shared pixel region, the second isolation pattern having an open region in a plan view, a plurality of photodiodes in the plurality of unit pixel regions, respectively, a plurality of floating diffusion regions in the plurality of unit pixel regions, the plurality of floating diffusion regions electrically connected to each other, and an inter-pixel overflow (IPO) gate overlapping the open region in the plan view. Each of the plurality of floating diffusion regions in each of the plurality of shared pixels may be spaced apart from the IPO gate in each of the plurality of shared pixels.

According to an aspect of an example embodiment of the disclosure, there is provided an image sensor including: a substrate having a first surface, a first isolation pattern defining a plurality of shared pixel regions in the substrate, and a plurality of shared pixels respectively in the plurality of shared pixel regions. Each of the plurality of shared pixels may include a plurality of photodiodes included in a corresponding shared pixel region, an inter-pixel overflow (IPO) barrier between the plurality of photodiodes in the corresponding shared pixel region, and an IPO gate overlapping the IPO barrier in a vertical direction, which is perpendicular to the first surface.

According to an aspect of an example embodiment of the disclosure, there is provided an image sensor including: a substrate including a shared pixel region therein, a plurality of photodiodes included in the shared pixel region, and an inter-pixel overflow (IPO) gate extending from a surface of the substrate to a region, inside the substrate, defined between the plurality of photodiodes.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a block diagram of an image sensor according to one or more example embodiments of the disclosure;

FIG. 2 is a circuit diagram of a shared pixel according to one or more example embodiments of the disclosure;

FIG. 3 is a diagram of an inter-pixel overflow (IPO) barrier potential of a shared pixel region according to one or more example embodiments of the disclosure;

FIG. 4 is a plan view of a portion of an image sensor according to one or more example embodiments of the disclosure;

FIG. 5 is a cross-sectional view taken along line I-I′ of FIG. 4;

FIG. 6 is a cross-sectional view taken along line II-II′ of FIG. 4;

FIG. 7 is a cross-sectional view taken along line III-III′ of FIG. 4;

FIG. 8 is a diagram of an IPO barrier potential of a shared pixel region according to one or more example embodiments of the disclosure;

FIG. 9 is a plan view of a portion of an image sensor one or more example embodiments of the disclosure. FIG. 10 is a cross-sectional view taken along line V-V′ of FIG. 9;

FIG. 11 is a plan view of a portion of an image sensor according to one or more example embodiments of the disclosure;

FIGS. 12 to 15 are plan views of a pixel array according to one or more example embodiments of the disclosure;

FIGS. 16 to 22 are diagrams of a method of manufacturing the image sensor illustrated in FIG. 10; and

FIGS. 23 and 24 are cross-sectional views of an image sensor according to one or more example embodiments of the disclosure.

### DETAILED DESCRIPTION

Hereinafter, example embodiments of the disclosure will be described with reference to the accompanying drawings.

In the following embodiments, terms, such as first and second, are used not in a limiting sense but for the purpose of distinguishing one component from another component.

In the following embodiments, singular terms include plural terms unless the context clearly dictates otherwise.

In the drawings, sizes of components may be exaggerated or reduced for convenience of explanation. For example, a size and a thickness of each component shown in the drawings may be arbitrarily shown for convenience of explanation.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

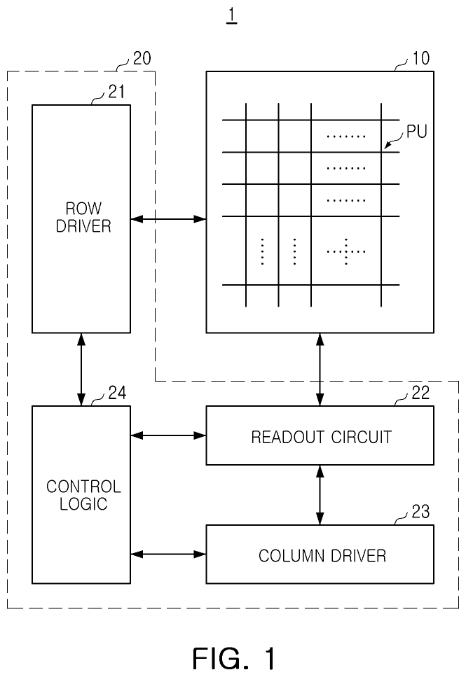

FIG. 1 is a block diagram of an image sensor according to one or more example embodiments of the disclosure.

Referring to FIG. 1, an image sensor 1 according to one or more example embodiments of the disclosure may include a pixel array 10 and a logic circuit 20.

The pixel array 10 may include a plurality of shared pixels PU arranged in an array form along a plurality of rows and a plurality of columns. Each of the shared pixels PU may include a plurality of photoelectric conversion devices configured to generate electrons in response to light, and a pixel circuit configured to generate a pixel signal corresponding to the electrons generated by the plurality of photoelectric conversion devices.

The photoelectric conversion device may include a photodiode, which includes a semiconductor material, and/or an organic photodiode, which includes an organic material. In an example embodiment, each of the shared pixels PU may include a first photodiode and a second photodiode, and the first photodiode and the second photodiode, included in a single shared pixel PU, may receive light having the same wavelength band to respectively generate electrons.

The pixel circuit may include a transmission transistor, a driving transistor, a selection transistor, and a reset transistor. When each of the shared pixels PU has two or more photoelectric conversion devices, the pixel circuit may share at least some of the transmission transistor, the driving transistor, the selection transistor, and the reset transistor.

The logic circuit 20 may include circuits for controlling the pixel array 10. For example, the logic circuit 20 may include a row driver 21, a readout circuit 22, a column driver 23, and a control logic 24.

The row driver 21 may drive the pixel array 10 in a row unit. For example, the row driver 21 may generate a transmission control signal for controlling the transmission transistor of the pixel circuit, a reset control signal for controlling the reset transistor, a selection control signal for controlling the selection transistor, and the like, and may input the generated signals to the pixel array 10 in a row unit.

The readout circuit 22 may include correlated double samplers (CDSs), an analog-to-digital converter (ADC), and the like. The correlated double samplers may be connected to the shared pixels PU through column lines. The correlated double samplers may receive a pixel signal from shared pixels PU connected to a row line selected by a row line selection signal of the row driver 21 to perform correlated double sampling. The pixel signal may be received through the column lines. The ADC may convert a pixel signal detected by the correlated double sampler into a digital pixel signal, and may transmit the digital pixel signal to the column driver 23.

The column driver 23 may include a latch or buffer circuit capable of temporarily storing a digital pixel signal, and an amplification circuit, and may process the digital pixel signal received from the readout circuit 22.

The row driver 21, the readout circuit 22, and the column driver 23 may be controlled by the control logic 24. The control logic 24 may include a timing controller for controlling operation timings of the row driver 21, the readout circuit 22, and the column driver 23.

When an excessive amount of light is introduced into some photoelectric conversion devices, among a plurality of photoelectric conversion devices included in a single shared pixel PU, the photoelectric conversion device may be saturated with electrons. The shared pixels PU may include an inter-pixel overflow (IPO) region, which provides a path through which electrons generated by the saturated photoelectric conversion device move to another photoelectric conversion device.

For example, a first isolation pattern for defining a shared pixel region of a substrate in which a single shared pixel is disposed may be provided, and a second isolation pattern for defining a unit pixel region of the shared pixel region in which each of the photoelectric conversion devices is disposed may be provided. The second isolation pattern may include an open region, and an IPO barrier may be formed in the open region.

The IPO barrier may have an IPO barrier potential. For example, when a potential level of a photoelectric conversion device is lower than a potential level of the IPO barrier due to electrons generated by the photoelectric conversion device, electrons generated by the photoelectric conversion device may move to another photoelectric conversion device through the IPO barrier.

In the shared pixel PU including the plurality of photoelectric conversion devices, the IPO barrier potential level may be one of important pixel properties. The IPO barrier potential level may be determined according to an impurity doping concentration distribution of the open region in the second isolation pattern, and may be controlled by adjusting a width of the open region.

A target potential level of the IPO barrier may be changed during designing the pixel array 10. However, in order to modify the width of the open region to change the IPO barrier potential level, a design layout of the pixel array 10 may need to be modified. When the design layout of the pixel array 10 is modified, a mask corresponding to the modified layout may need to be newly manufactured, and a period and cost for designing the pixel array 10 may increase.

According to an example embodiment of the disclosure, there are provided a structure of an image sensor capable of electronically controlling IPO barrier potential properties and a method of manufacturing the image sensor.

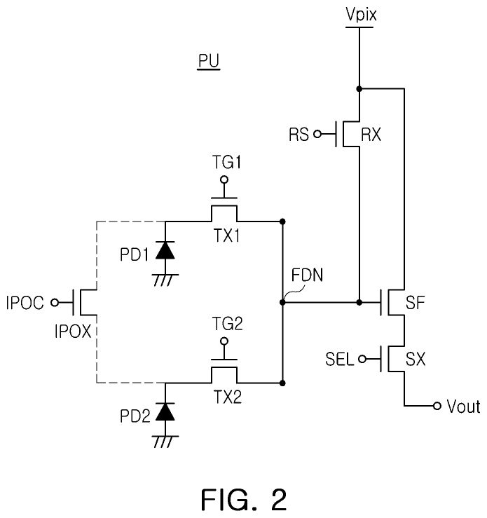

FIG. 2 is a circuit diagram of a shared pixel according to one or more example embodiments of the disclosure.

A shared pixel PU may include a plurality of photodiodes and a pixel circuit. For example, the shared pixel PU may include a first photodiode PD1 and a second photodiode PD2. Each of the two photodiodes PD1 and PD2 may be included in a single unit pixel. In a single shared pixel PU, the two photodiodes PD1 and PD2 may share a single floating diffusion node FDN.

The shared pixel PU may include a pixel circuit including a plurality of transmission transistors TX1 and TX2, a reset transistor RX, a source follower transistor SF, and a selection transistor SX.

A first transfer transistor TX1 may be connected to the first photodiode PD1 and the floating diffusion node FDN, and a second transfer transistor TX2 may be connected to the second photodiode PD2 and the floating diffusion node FDN.

The reset transistor RX may be turned on and off by a reset control signal RS. When the reset transistor RX is turned on, a voltage of the floating diffusion node FDN may be reset to a power supply voltage Vpix. When the voltage of the floating diffusion node FDN is reset, the selection transistor SX may be turned on by a selection control signal SEL, and thus a reset voltage may be outputted to a column line COL as an output voltage Vout.

When the first transfer transistor TX1 is turned on by a first control signal TG1 after the reset voltage is outputted to the column line COL, electrons, generated by exposure of the first photodiode PD1 to light, may move to the floating diffusion node FDN. The source follower transistor SF may operate as a source follower amplifier configured to amplify the voltage of the floating diffusion node FDN. When the selection transistor SX is turned on by the selection control signal SEL, a first pixel voltage, corresponding to the electrons generated by the first photodiode PD, may be outputted to the column line COL as the output voltage Vout.

When the second transfer transistor TX2 is turned on after the first pixel voltage is outputted to the column line COL, electrons, generated by exposure of the second photodiode PD2 to light, may move to the floating diffusion region FD. The source follower transistor SF may operate as a source follower amplifier configured to amplify the voltage of the floating diffusion node FDN. When the selection transistor SX is turned on by the selection control signal SEL, a second pixel voltage, corresponding to the electrons generated by the second photodiode PD2, may be outputted to the column line COL as the output voltage Vout.

Each of the reset voltage and the first and second pixel voltages may be detected by a sampling circuit connected to the column line COL. The sampling circuit may include a plurality of samplers, each having a first input terminal configured to receive the reset voltage, and a second input terminal configured to receive the first pixel voltage or the second pixel voltage.

The sampler may compare the reset voltage input to the first input terminal and the first pixel voltage input to the second input terminal to each other. An ADC may be connected to an output terminal of the sampler, and the ADC may output first image data corresponding to a result of comparing the reset voltage and the first pixel voltage to each other.

The sampler may compare the reset voltage input to the first input terminal and the second pixel voltage input to the second input terminal to each other. An ADC may be connected to an output terminal of the sampler, and the ADC may output second image data corresponding to a result of comparing the reset voltage and the second pixel voltage to each other.

A signal processing circuit may generate an image using the first image data and the second image data.

According to an example embodiment of the disclosure, the shared pixel PU may further include an IPO transistor IPOX selectively connecting the plurality of photodiodes PD1 and PD2 to each other. The IPO transistor IPOX may adjust, based on a voltage level of an IPO control signal IPOC, the IPO barrier potential level. Specifically, when the IPO control signal IPOC is applied to a gate of the IPO transistor IPOX, a channel may be formed between the first photodiode PD1 and the second photodiode PD2, thereby facilitating electron movement therebetween. That is, the IPO barrier potential level may increase.

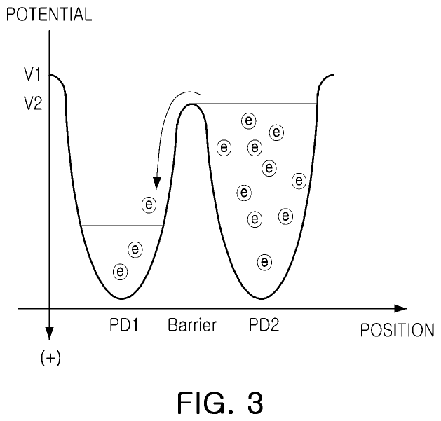

FIG. 3 is a diagram of an IPO barrier potential of a shared pixel region according to one or more example embodiments of the disclosure.

FIG. 3 illustrates a potential level according to a position in a shared pixel region. In FIG. 3, a position of a first photodiode PD1, a position of a second photodiode PD2, and a position of an IPO barrier between the first and second photodiodes PD1 and PD2 represented on an X-axis are illustrated.

In a substrate having a shared pixel region, an internal isolation pattern may be disposed between the first and second photodiodes PD1 and PD2. An IPO barrier may be provided between the first and second photodiodes PD1 and PD2 due to a difference between a potential level of the internal isolation pattern and a potential level of the first and second photodiodes PD1 and PD2.

While the first and second photodiodes PD1 and PD2 perform photoelectric conversion, when light having a reference illuminance or greater is incident on the first and second photodiodes PD1 and PD2, the photodiodes are saturated, and electrons having a full well capacity or greater may be generated. Electrons additionally generated by the saturated photodiode may leak into the floating diffusion region in the photodiode even when a transmission transistor connected to the photodiode is turned off. The leaked electrons may be discharged by a reset operation of a shared pixel, and thus a signal loss may occur.

In order to reduce a signal loss, a potential level of the IPO barrier may be adjusted. FIG. 3 illustrates a first barrier potential level V1 between a photodiode and a floating diffusion region and an IPO barrier potential level V2 between the first and second photodiodes PD1 and PD2, in a state in which a transmission transistor connected to the photodiode is turned off. The IPO barrier potential level V2 may be adjusted to a level higher than the first barrier potential level V1. For example, the internal isolation pattern may have an open region, and the IPO barrier potential level V2 may be adjusted according to a width of the open region. As a potential level decreases, energy of electrons may increase.

For example, light having the reference illuminance or greater may be incident on the second photodiode PD2, and electrons of the photodiodes having the full well capacity or greater may be generated. When the first barrier potential level V1 is lower than the IPO barrier potential level V2, electrons additionally generated by the second photodiode PD2 may pass through the IPO barrier and move to the first photodiode PD1, thereby preventing loss of a signal of a shared pixel.

The IPO barrier potential properties, that is, the IPO barrier potential level V2, may be associated with the full well capacity of each of the photodiodes. When an image sensor is designed, a target potential level of the IPO barrier may be determined. In addition, the target potential level of the IPO barrier may be modified.

According to an example embodiment of the disclosure, the image sensor may include an IPO transistor, and may electronically control an IPO barrier potential level, based on a voltage level applied to the IPO transistor. Hereinafter, an image sensor according to an example embodiment of the disclosure will be described in detail.

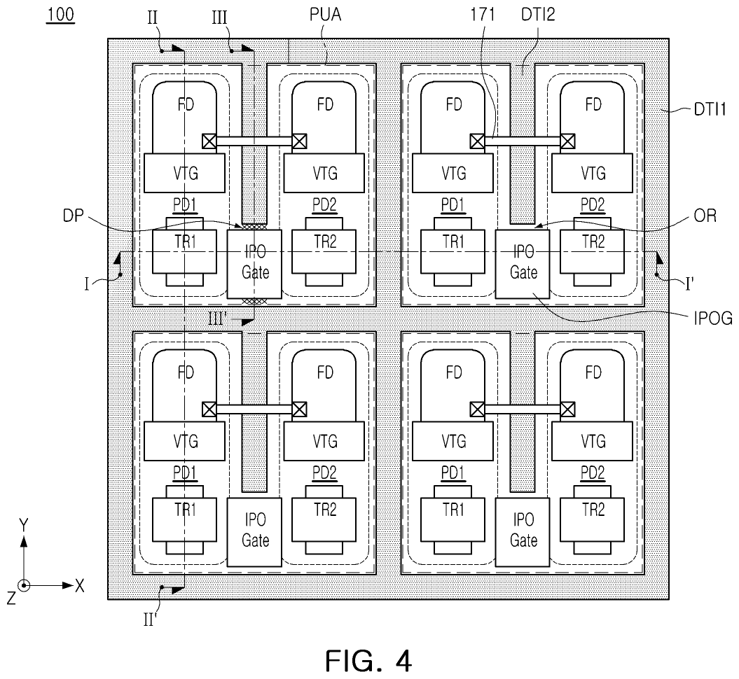

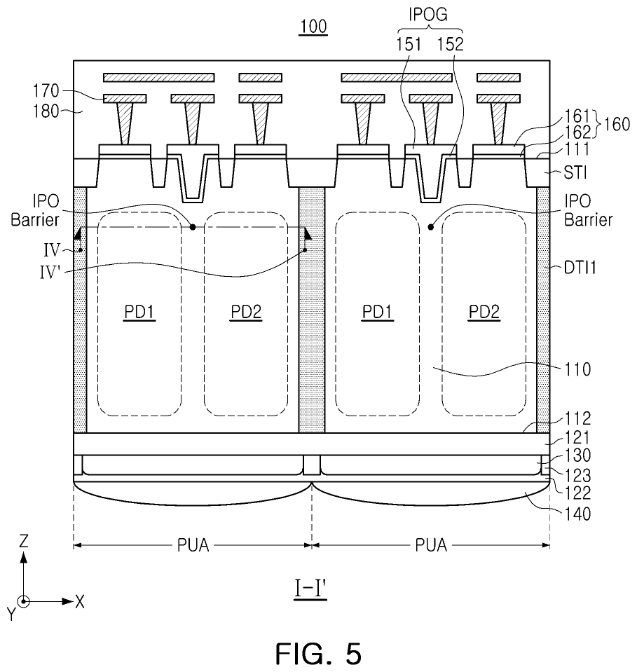

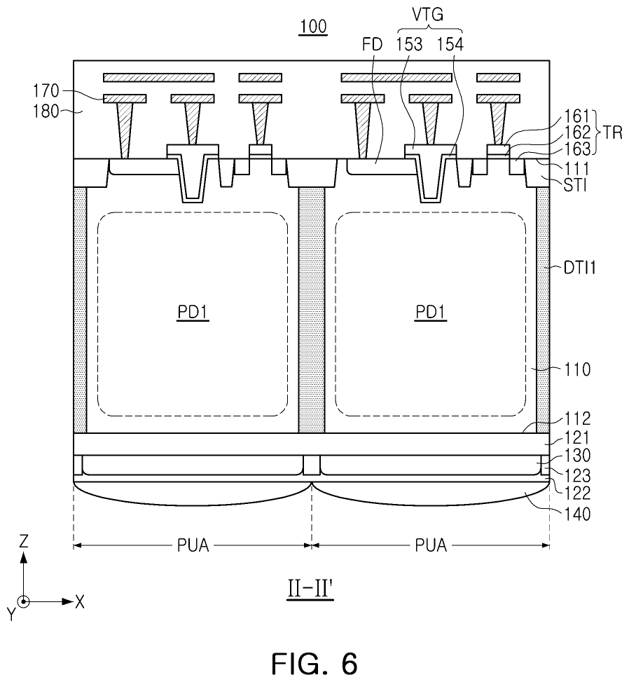

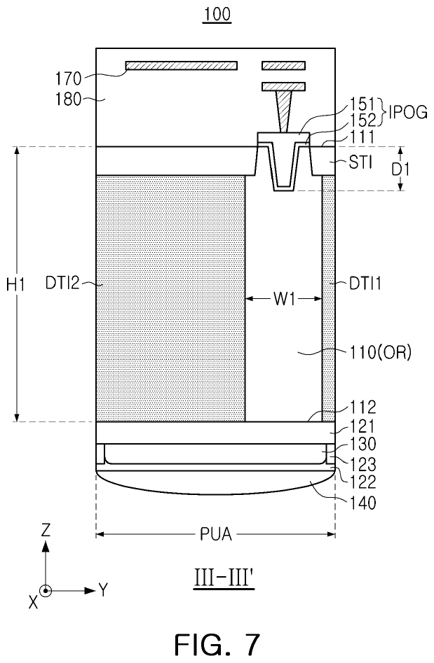

FIG. 4 is a plan view of a portion of an image sensor according to one or more example embodiments of the disclosure. FIG. 5 is a cross-sectional view taken along line I-I′ of FIG. 4, FIG. 6 is a cross-sectional view taken along line II-II′ of FIG. 4, and FIG. 7 is a cross-sectional view taken along line III-III′ of FIG. 4.

Referring to FIGS. 4 to 7, an image sensor 100 may include a plurality of shared pixels PU. The image sensor 110 may include a substrate 110. The substrate 110 may have a first surface 111 and a second surface 112, opposing each other.

A first isolation pattern DTI1, defining a plurality of shared pixel regions PUA, may be disposed in the substrate 110. The first isolation pattern DTI1 may prevent crosstalk between the plurality of shared pixel regions PUA, and may prevent optical interference between the plurality of shared pixel regions PUA. The first isolation pattern DTI1 may include an insulating material such as an oxide or the like, and a sidewall of the first isolation pattern DTI1 may include a material having high reflectivity. The plurality of shared pixels PU may be disposed along the plurality of shared pixel regions PUA.

The first isolation pattern DTI1 may have a lattice shape in an X-Y plane, and may extend in a third direction Z. The X-Y plane may be a plane, parallel to the first and second surfaces 111 and 112 of the substrate 110, and the third direction Z may be perpendicular to the first and second surfaces 111 and 112. However, the disclosure is not limited to an embodiment in which the first isolation pattern DTI has a lattice shape.

FIG. 4 illustrates a portion of the image sensor 100 with respect to the first surface 111 of the substrate 110. Referring to FIG. 4, the plurality of shared pixel regions PUA may be defined by the first isolation pattern DTI1 and arranged in a first direction X and a second direction Y.

Each of the shared pixel regions PUA may include a second isolation pattern DTI2 defining a plurality of unit pixel regions. The second isolation pattern DTI2 may have an open region OR. In the example of FIG. 4, the second isolation pattern DTI2 may extend from a first edge, among a plurality of edges of the first isolation pattern DTI1, in a direction toward a second edge opposing the first edge, and may have the open region OR adjacent to the second edge.

In an example embodiment, side surfaces of the first isolation pattern DTI1 and the second isolation pattern DTI2 may be doped with impurities. For example, the side surfaces of the first isolation pattern DTI1 and the second isolation pattern DTI2 may be doped with P-type impurities having a concentration higher than that of the substrate 110. FIG. 4 illustrates only a doped region DP formed in a single open region OR.

A plurality of photodiodes PD1 and PD2 may be disposed in each of the plurality of unit pixel regions. The plurality of photodiodes PD1 and PD2 may generate electric charges in response to light. In an example embodiment, each of the plurality of photodiodes PD1 and PD2 may include an N-type impurity doped region. In an example embodiment, the plurality of photodiodes PD1 and PD2 may generate electrons as a main charge carrier.

A plurality of floating diffusion regions FD may be included between each of the plurality of photodiodes PD1 and PD2 and the first surface 111 in a shared pixel region PUA. Each of the plurality of floating diffusion regions FD may be disposed in a position overlapping a corresponding photodiode in the third direction Z. The plurality of floating diffusion regions FD included in the single shared pixel region PUA may be electrically connected to each other through a conductive pattern 171, and thus may be included in a single floating diffusion node FDN, the same as that described with reference to FIG. 2.

A transfer gate VTG may be disposed in a position overlapping each of the plurality of photodiodes PD1 and PD2 in the third direction Z. In an example embodiment, the transfer gate VTG may include a vertical structure extending from the first surface 111 to an inside of the unit pixel region. The transfer gate VTG may be, together with the photodiode and the floating diffusion region FD, included in the transfer transistor TX, the same as that described with reference to FIG. 2.

The shared pixel PU may further include a plurality of transistors TR1 and TR2. In an example embodiment, the plurality of transistors may provide a reset transistor RX, a source follower transistor SF, and a selection transistor SX, the same as those described with reference to FIG. 2. Unit pixels, included in the shared pixel PU, may share the plurality of transistors TR1 and TR2. In FIG. 4, two transistors TR1 and TR2 disposed in a single shared pixel region PUA are illustrated, but the number and position of transistors disposed in a single shared pixel region PUA are not limited to the example of FIG. 4.

An IPO barrier may be formed in the open region OR. When at least one of the plurality of photodiodes PD1 and PD2 is saturated with electrons, electrons generated from the saturated photodiode may pass through the IPO barrier and move to another photodiode. That is, when electrons are accumulated in a photodiode and a potential level of the photodiode is lower than the IPO barrier potential level, electrons may pass through the IPO barrier.

The IPO barrier potential level may be determined according to an impurity doping concentration distribution of the open region OR. The side surfaces of the first and second isolation patterns DTI1 and DTI2 may be doped with impurities, and the impurity doping concentration distribution of the open region OR may vary depending on a width of the open region OR. When the width of the open region OR needs to be modified to control the IPO barrier potential level, a design layout of the image sensor may need to be modified.

According to an example embodiment of the disclosure, the image sensor 100 may include an IPO gate IPOG overlapping the open region in the third direction Z. The IPO gate IPOG may be included in the IPO transistor IPOX, described with reference to FIG. 2, together with the first and second photodiodes PD1 and PD2.

The image sensor 100 may electronically control the IPO barrier potential level by applying a voltage to the IPO gate IPOG. Accordingly, even when the design layout of the image sensor 100 is not modified, the IPO barrier potential level may be changed, and cost and time for designing the image sensor 100 having target IPO barrier potential properties may be reduced.

Referring to FIG. 5, the first isolation pattern DTI1 may have a front deep trench isolation (FDTI) structure. For example, the first isolation pattern DTI1 may be in contact with a device isolation pattern STI formed to be in contact with the first surface 111, and the first isolation pattern DTI1 may also be in contact with the second surface 112.

In an example embodiment, the second isolation pattern DTI2, described with reference to FIG. 4, may also have an FDTI structure in the same manner as the first isolation pattern DTI1. In an example embodiment, a width of the first isolation pattern DTI1 may be equal to a width of the second isolation pattern DTI2. However, the structures of the first isolation pattern DTI1 and the second isolation pattern DTI2 are not limited thereto.

In the shared pixel region PUA, a pixel circuit may be disposed around the first surface 111. According to an example embodiment of the disclosure, the pixel circuit may include the IPO gate IPOG having a portion extending from the first surface 111 to an inside of the substrate 110. The IPO gate IPOG may include a gate electrode 151 having a structure extending to the inside of the substrate 110, and a gate insulating layer 152 between the gate electrode 151 and the substrate 110.

According to an example embodiment of the disclosure, the IPO gate IPOG may overlap the IPO barrier in the third direction Z, perpendicular to the first surface 111. The IPO barrier may be formed between the first and second photodiodes PD1 and PD2.

The IPO barrier may refer to a position having a highest potential level and a lowest energy level in the open region OR. When a potential level of one of the first and second photodiodes PD1 and PD2 is lower than the IPO barrier potential level, electrons accumulated in the photodiode may move to another photodiode through the IPO barrier.

A gate structure 160 may be disposed on the first surface 111. The gate structure 160 may include a gate electrode 161 on the first surface 111, and a gate insulating layer 162 between the gate electrode 161 and the first surface 111. The gate structure 160 may be included in the first and second transistors TR1 and TR2 of FIG. 4. The gate structure 160 may have a planar gate structure.

The pixel circuit may include conductive patterns (or interconnection patterns) 170 for connecting a plurality of devices to each other on the first surface 111, and an insulating layer 180 covering the plurality of devices and the conductive patterns 170.

A light transmission structure may be disposed on the second surface 112 of the substrate 110. The light transmission structure may include a first planarization film 121, a color filter 130, a second planarization film 122, and a microlens 140, which are sequentially stacked on the second surface 112.

The light transmission structure may further include an anti-reflection film 123 formed on the first planarization film 121. The anti-reflection film 123 may overlap the isolation pattern DTI1 in the third direction Z. A sidewall of the anti-reflection film 123 may be in contact with a color filter CF. The anti-reflection film 123 may prevent light passing through the color filter CF from incident onto another shared pixel region PUA. The anti-reflection film 123 may include a metal. For example, the anti-reflection film 123 may include tungsten (W), aluminum (Al), copper (Cu), or combinations thereof.

When a voltage is applied to the IPO gate IPOG through the conductive pattern 170, a channel may be formed around the IPO gate IPOG in the substrate 110. Electrons may move between the first photodiode PD1 and the second photodiode PD2 through the channel.

A region in which the channel is formed may include an IPO barrier. For example, the IPO barrier may be formed at a depth of 0.5 um from the first surface 111 of the substrate 110, and the IPO gate IPOG may extend from the first surface 111 to a depth of 0.3 um to 0.4 um. When a voltage is applied to the IPO gate IPOG, a channel may be formed in the IPO barrier, and electrons may smoothly move between the first photodiode PD1 and the second photodiode PD2 through the IPO barrier. The smooth movement of the electrons may mean that a potential level of the IPO barrier increases and an energy level of the IPO barrier decreases.

The potential level of the IPO barrier may vary depending on a level of the voltage applied to the IPO gate IPOG. Accordingly, the image sensor 100 may control the potential level of the IPO barrier by adjusting the level of the voltage applied to the IPO gate IPOG.

The example of FIG. 5 illustrates a case in which a channel is formed in the IPO barrier, but the disclosure is not limited thereto. A depth at which the IPO barrier is formed with respect to the first surface 111 may vary depending on dimensions of a shared pixel region and an impurity doping concentration of the shared pixel region. For example, the IPO barrier may be formed in a position deeper than a position in which the channel is formed with respect to the first substrate 111.

However, when a channel is formed around the IPO gate IPOG, a barrier potential level of a region in which the channel is formed may be higher than a barrier potential level of the IPO barrier. As a result, the region in which the channel is formed may become a new IPO barrier.

Referring to FIG. 6, the transfer gate VTG may have a structure extending from the first surface 111 toward a photodiode in the shared pixel region PUA. In the example of FIG. 6, the transfer gate VTG having a structure extending in the third direction Z from the first surface 111 toward the first photodiode PD1 is illustrated. The floating diffusion region FD may be disposed in the first surface 111. The transfer gate VTG may be in contact with the floating diffusion region FD. The transfer gate VTG, the floating diffusion region FD, and the photodiode may be included in the transfer transistor TX, described with reference to FIG. 2.

An active region 163 may be disposed in the first surface 111. The active region 163 may be, together with the gate structure 160, included in the first and second transistors TR1 and TR2. In an example embodiment, the first and second transistors TR1 and TR2 may have a planar transistor structure.

The transfer gate VTG may include a gate electrode 153 having a portion extending to the inside of the substrate 110, and a gate insulating layer 154 between the gate electrode 153 and the substrate 110. According to an example embodiment of the disclosure, the gate electrode 151 of the IPO gate IPOG and the gate electrode 153 of the transfer gate VTG may include the same material. In addition, the gate insulating layer 152 of the IPO gate IPOG and the gate insulating layer 154 of the transfer gate VTG may include the same material. In an example embodiment, the IPO gate IPOG and the transfer gate VTG may extend to substantially the same depth with respect to the first surface 111.

According to an example embodiment of the disclosure, the IPO gate IPOG may be formed in a manufacturing process the same as or similar to that of the transfer gate VTG. That is, an additional manufacturing process may not be required to form the IPO gate IPOG capable of controlling the potential level of the IPO barrier, thereby preventing an increase in a period and cost for manufacturing the image sensor 100 capable of electronically controlling the IPO barrier potential level.

However, the disclosure is not limited to the case in which the transfer gate VTG has a vertical gate structure. For example, the transfer gate VTG may have a planar gate structure.

Referring to FIG. 7, a first thickness H1 of the substrate 110, a first width W1 of the open region OR, and a first depth D1 of the IPO gate IPOG are illustrated.

The first thickness H1 of the substrate 110 may indicate a length of the substrate 110 in the third direction Z. The first width W1 of the open region OR may indicate a length of the open region OR in a direction in which the second isolation pattern DTI2 extends. In the example of FIG. 7, the first width W1 may be defined as a distance between the first isolation pattern DTI1 and the second isolation pattern DTI2 in the direction in which the second isolation pattern DTI2 extends. The first depth D1 of the IPO gate IPOG may indicate a length of a portion of the IPO gate IPOG, extending to the inside of the substrate 110, in the third direction Z.

In an example embodiment, the first depth D1 of the IPO gate IPOG may have a value of 1 to 2 times the first width W1 of the open region OR. The first depth D1 may have a value of 7% to 14% of the first thickness H1 of the substrate 110.

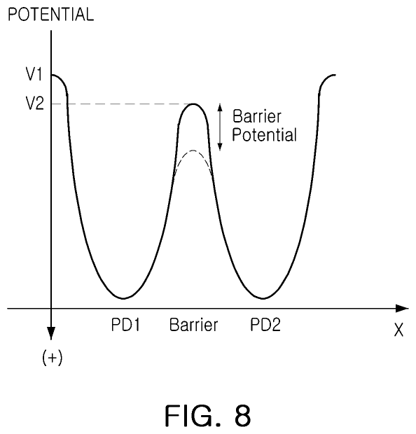

FIG. 8 is a diagram of an IPO barrier potential of a shared pixel region according to one or more example embodiments of the disclosure.

Specifically, FIG. 8 illustrates a potential level according to a position in the shared pixel region along the line IV-IV′ of FIG. 4, which is expressed along an X-axis of the diagram of FIG. 8. In FIG. 8, a position of the first photodiode PD1, a position of the second photodiode PD2, and a position of the IPO barrier between the first and second photodiodes PD1 and PD2 are illustrated. As shown in FIG. 8, a potential level of the IPO barrier may be controlled by adjusting a level of a voltage applied to an IPO gate.

An image sensor according to an example embodiment of the disclosure may electronically control a potential level of the IPO barrier by adjusting a level of a voltage applied to an IPO gate. Accordingly, the image sensor may have target IPO barrier potential properties without changing a design layout thereof.

Referring to FIGS. 4 to 7, an example embodiment of the disclosure has been described as an example in which an IPO gate IPOG has a vertical gate structure. However, the disclosure is not limited thereto. According to an example embodiment of the disclosure, the IPO gate may have a planar gate structure.

Referring to FIGS. 4 to 8, an example embodiment of the disclosure has been described as an example in which a second isolation pattern DTI2 of each of shared pixel regions PUA has a deep trench isolation (DTI) edge cut (DEC) structure having an open region OR adjacent to an edge of a first isolation pattern DTI1. However, the disclosure is not limited thereto. For example, according to an example embodiment of the disclosure, the image sensor may have a DTI center cut (DCC) structure in which a central portion of each of the shared pixel regions has an open region.

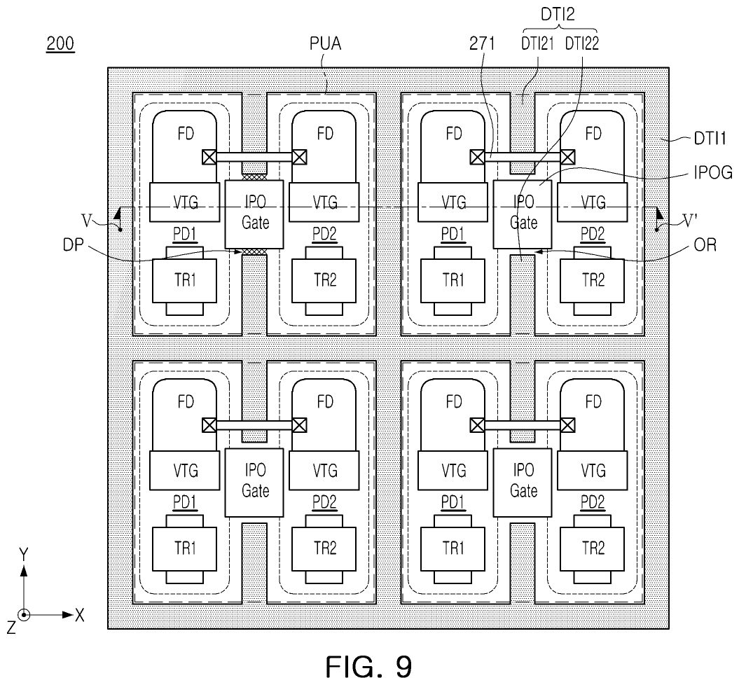

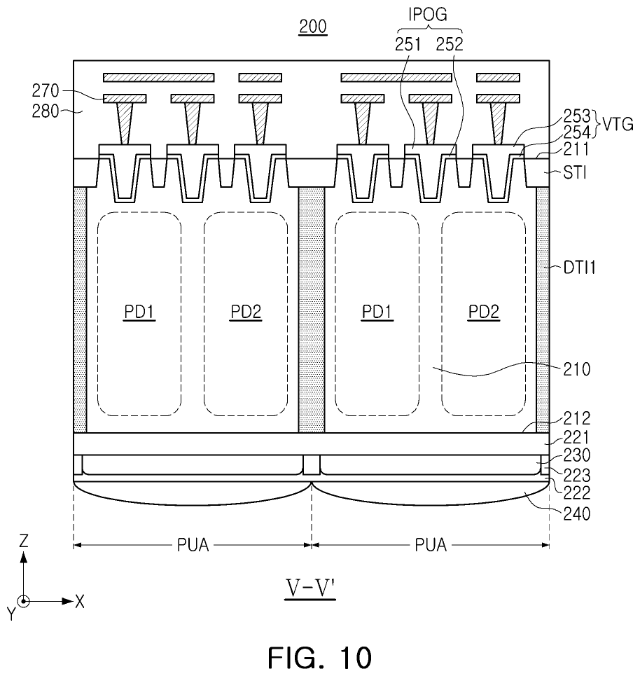

Hereinafter, an image sensor according to an example embodiment of the disclosure will be described with reference to FIGS. 9 and 10.

FIG. 9 is a plan view of a portion of an image sensor an example embodiment of the disclosure. FIG. 10 is a cross-sectional view taken along line V-V′ of FIG. 9.

Referring to FIGS. 9 and 10, an image sensor 200 may include a plurality of shared pixels PU. The image sensor 200 may include a substrate 210 having a first surface 211 and a second surface 212, opposing each other.

A first isolation pattern DTI1, defining a plurality of shared pixel regions PUA, may be disposed in the substrate 210. A shape and a material of the first isolation pattern DTI1 may be the same as or similar to those described with reference to FIGS. 4 to 7.

FIG. 9 illustrates a portion of the image sensor 200 with respect to the first surface 211 of the substrate 210. Referring to FIG. 9, the plurality of shared pixel regions PUA may be defined by the first isolation pattern DTI1 and arranged in a first direction X and a second direction Y.

The shared pixel region PUA may include a second isolation pattern DTI2 defining a plurality of unit pixel regions. The second isolation pattern DTI2 may have an open region OR. In the example of FIG. 9, the second isolation pattern DTI2 may include a first sub-isolation pattern DTI21 extending from a first edge, among a plurality of edges of the first isolation pattern DTI1, in a second direction Y, a second sub-isolation pattern DTI22 extending from a second edge opposing the first edge in a second direction Y, among the plurality of edges, and the open region OR between the first and second sub-isolation patterns DTI21 and DTI22. In an example embodiment, the open region OR may be positioned in a central portion of the shared pixel region PUA.

In an example embodiment, side surfaces of the first isolation pattern DTI1 and the second isolation pattern DTI2 may be doped with impurities. For example, the side surfaces of the first isolation pattern DTI1 and the second isolation pattern DTI2 may be doped with P-type impurities having a concentration higher than that of the substrate 210. FIG. 10 illustrates only a doped region DP formed in a single open region OR.

A plurality of photodiodes PD1 and PD2 may be disposed in each of the plurality of unit pixel regions. A plurality of floating diffusion regions FD may be included between each of the plurality of photodiodes PD1 and PD2 and the first surface 211 in the shared pixel region PUA. The plurality of floating diffusion regions FD included in a single shared pixel region PUA may be electrically connected to each other through a conductive pattern 271, and thus may be included in a single floating diffusion node FDN.

A transfer gate VTG may be disposed in a position overlapping each of the plurality of photodiodes PD1 and PD2 in a third direction Z. The transfer gate VTG may be, together with the photodiode and the floating diffusion region FD, included in a transfer transistor TX, the same as that described with reference to FIG. 2. In an example embodiment, the transfer gate VTG may have a vertical gate structure, as described with reference to FIGS. 4 to 7. In an example embodiment, the transfer gate VTG may have a planar gate structure.

As described with reference to FIGS. 4 to 7, the shared pixel PU may further include a plurality of transistors TR1 and TR2. In an example embodiment, the plurality of transistors may provide a reset transistor RX, a source follower transistor SF, and a selection transistor SX, the same as those described with reference to FIG. 2

Referring to FIG. 10, the first isolation pattern DTI1 may have an FDTI structure. The second isolation pattern DTI2, described with reference to FIG. 10, may also have an FDTI structure in the same manner as the first isolation pattern DTI1.

In the shared pixel region PUA, a pixel circuit may be disposed around the first surface 211. The pixel circuit may include an IPO gate IPOG and a transfer gate VTG having a portion extending from the first surface 211 to the inside of the substrate 210. The IPO gate IPOG may include a gate electrode 251 having a structure extending to the inside of the substrate 210, and a gate insulating layer 252 between the gate electrode 251 and the substrate 210. The transfer gate VTG may include a gate electrode 253 having a portion extending to the inside of the substrate 210, and a gate insulating layer 254 between the gate electrode 253 and the substrate 210.

The pixel circuit may include conductive patterns 270 for connecting a plurality of devices to each other on first surface 111, and an insulating layer 280 covering the plurality of devices and the conductive patterns 270.

A light transmission structure may be disposed on the second surface 212 of the substrate 210. The light transmission structure may include a first planarization film 221, a color filter 230, a second planarization film 222, and a microlens 240, which are sequentially stacked on the second surface 212, and may further include an anti-reflection film 223 formed between the first planarization films 221. A structure of the light transmission structure of the image sensor 200 may be the same as or similar to that described with reference to FIG. 5.

According to an example embodiment of the disclosure, the IPO gate IPOG may overlap an IPO barrier in the third direction Z, perpendicular to the first surface 111. The IPO barrier may be formed between the first and second photodiodes PD1 and PD2.

When a voltage is applied to the IPO gate IPOG through the conductive pattern (or interconnection pattern) 270, a channel may be formed around the IPO gate IPOG in the substrate 210. Electrons may smoothly move between the first photodiode PD1 and the second photodiode PD2 through the channel. That is, an IPO barrier voltage may increase.

The image sensor according to an example embodiment of the disclosure is not limited to a case in which each of the shared pixels has two photodiodes. For example, each of the shared pixels of the image sensor according to an example embodiment of the disclosure may have three or more photodiodes.

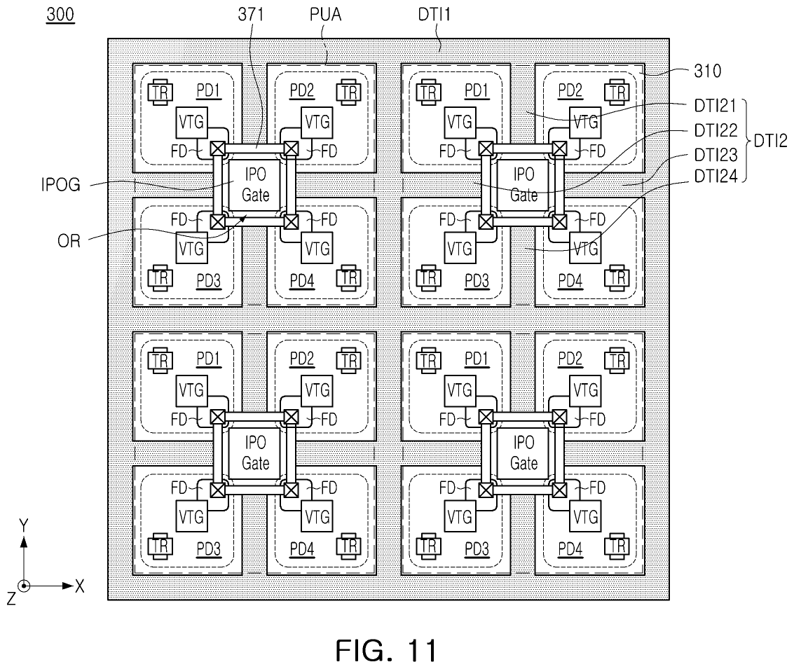

FIG. 11 is a plan view of a portion of an image sensor according to one or more example embodiments of the disclosure.

Referring to FIG. 11, an image sensor 300 may include a plurality of shared pixel regions PUA. A first isolation pattern DTI1, defining the plurality of shared pixel regions PUA, may be disposed in a substrate 310 of the image sensor 300. A shape and a material of the first isolation pattern DTI1 may be the same as or similar to those described with reference to FIGS. 4 to 7. A plurality of shared pixels may be disposed in a first direction X and a second direction Y along the plurality of shared pixel regions PUA.

The shared pixel region PUA may include a second isolation pattern DTI2, defining a plurality of unit pixel regions. The second isolation pattern DTI2 may have an open region OR. In the example of FIG. 11, the second isolation pattern DTI2 may include first to fourth sub-isolation patterns DTI21, DTI22, DTI23, and DTI24 respectively extending from a plurality of edges of the first isolation pattern DTI1 to a central portion of the shared pixel region, and an open region OR of the central portion of the shared pixel region. In an example embodiment, side surfaces of the first isolation pattern DTI1 and the second isolation pattern DTI2 may be doped with impurities.

A plurality of photodiodes PD1, PD2, PD3, and PD4 may be disposed in each of the plurality of unit pixel regions. A plurality of floating diffusion regions FD may be included around the plurality of photodiodes PD1 to PD4 in the shared pixel region PUA. The plurality of floating diffusion regions FD included in the single shared pixel region PUA may be electrically connected to each other through a conductive pattern 371, and thus may be included in a single floating diffusion node FDN.

A transfer gate VTG may be disposed in a position overlapping each of the plurality of photodiodes PD1 to PD4 in a third direction Z. The transfer gate VTG may be, together with the photodiode and the floating diffusion region FD, included in a transfer transistor TX, the same as that described with reference to FIG. 2. In an example embodiment, the transfer gate VTG may have a vertical gate structure, as described with reference to FIGS. 4 to 7. In an example embodiment, the transfer gate VTG may have a planar gate structure.

A plurality of transistors TR may be further disposed in the shared pixel region PUA. In an example embodiment, a plurality of transistors may provide a reset transistor RX, a source follower transistor SF, and a selection transistor SX, the same as those described with reference to FIG. 2.

An IPO barrier may be formed in the open region OR between the plurality of photodiodes PD1 to PD4. When one or more photodiodes, among the plurality of photodiodes PD1 to PD4, are saturated with electrons, electrons generated by the saturated photodiode(s) may move to another photodiode through the IPO barrier. According to an example embodiment of the disclosure, an IPO gate IPOG may overlap the IPO barrier in the third direction Z.

When a voltage is applied to the IPO gate IPOG through an interconnection pattern, a channel may be formed around the IPO gate IPOG in the substrate 310. Electrons may smoothly move between the plurality of photodiodes PD1 to PD4 through the channel. That is, an IPO barrier voltage may increase.

The shared pixels, described with reference to FIGS. 2 to 11, may be included in a pixel array 10, the same as that described with reference to FIG. 1.

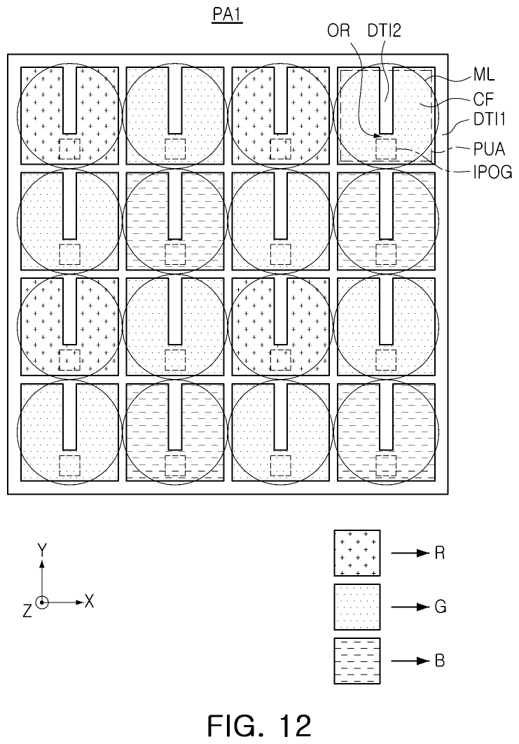

FIGS. 12 to 15 are plan views of a pixel array according to one or more example embodiments of the disclosure.

Referring to FIG. 12, a pixel array PA1 may include a plurality of shared pixel regions PUA defined by a first isolation pattern DTI1 and arranged in a first direction X and a second direction Y. Shared pixels may be disposed in each of the shared pixel regions.

Each of the shared pixel regions PUA may include a plurality of photodiodes therein. Each of the shared pixel regions PUA may include a second isolation pattern DTI2 defining unit pixel regions, and each of the plurality of photodiodes may be disposed in the unit pixel regions.

The plurality of photodiodes may convert light incident through a microlens ML disposed above the shared pixel regions PUA into electric charges. Electric charges, accumulated in the photodiodes, may be transferred to a floating diffusion node PDN, the same as that described with reference to FIG. 2. The shared pixel may generate an image signal, based on the electric charges transferred to the floating diffusion node PDN.

The pixel array PA1 may include color filters. The color filters may receive light passing through the microlens, and may transmit light having a wavelength, corresponding to a wavelength having a predetermined range, of the received light. For example, each of the color filters may transmit light having a wavelength, corresponding to a wavelength of one color, for example, red (R), green (G), and blue (B), of the received light. In the example of FIG. 12, the color filters may be arranged in a Bayer pattern in each of the shared pixel regions.

The second isolation pattern DTI2 may have an open region OR. In the example of FIG. 12, the shared pixel regions may have a DEC structure having an open region OR adjacent to an edge of the first isolation pattern DTI1. An IPO barrier may be formed in the open region OR between the plurality of photodiodes.

According to an example embodiment of the disclosure, an IPO gate IPOG, overlapping in a third direction Z, may be disposed on an IPO barrier of each of the plurality of shared pixel regions PUA. An image sensor may control an IPO barrier potential level by adjusting a level of a voltage applied to each of IPO gates IPOGs included in a pixel array PA.

In an example embodiment, voltages having the same level may be respectively applied to the IPO gates IPOGs. However, the disclosure is not limited thereto.

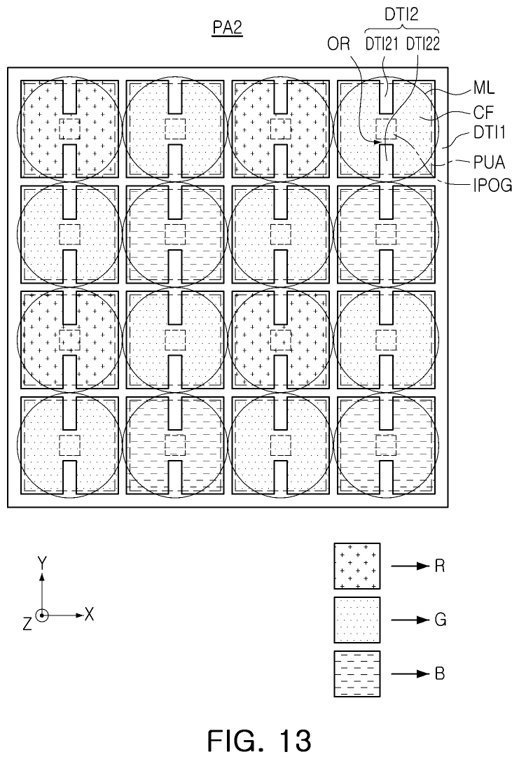

Referring to FIG. 13, a pixel array PA2 may have a structure similar to that of the pixel array PA1 described with reference to FIG. 12. However, the pixel array PA2 may have a DCC structure in which a central portion of a shared pixel region has an open region OR.

According to an example embodiment of the disclosure, an IPO gate IPOG, overlapping in the third direction Z, may be disposed on an IPO barrier of each of the plurality of shared pixel regions PUA. An image sensor may control an IPO barrier potential level by adjusting a level of a voltage applied to each of IPO gates IPOGs included in the pixel array PA.

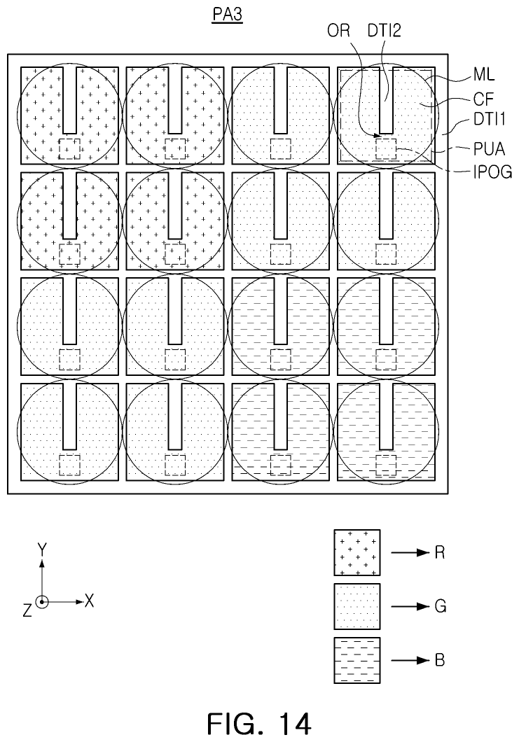

Referring to FIG. 14, a pixel array PA3 may have a structure similar to that of the pixel array PA1 described with reference to FIG. 12. However, color filters may be arranged in a quad-layer pattern in each of shared pixel regions of the pixel array PA3.

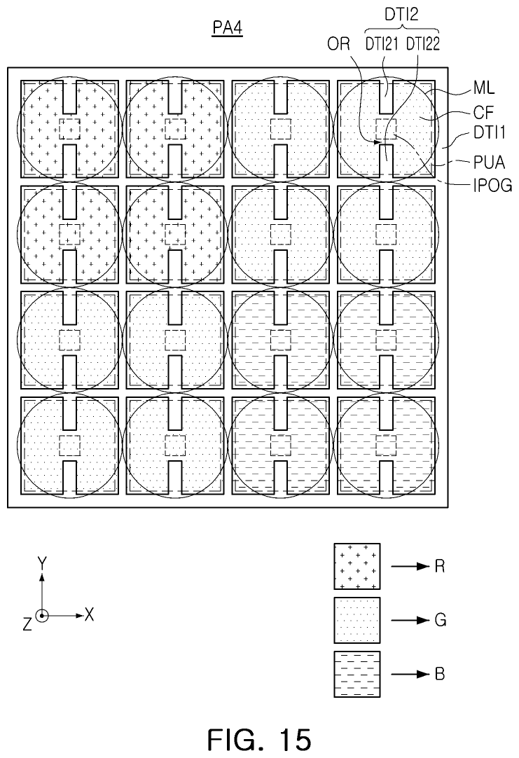

Referring to FIG. 15, a pixel array PA4 may have a structure similar to that of the pixel array PA2 described with reference to FIG. 13. However, color filters may be arranged in a quad-layer pattern in each of shared pixel regions of the pixel array PA4.

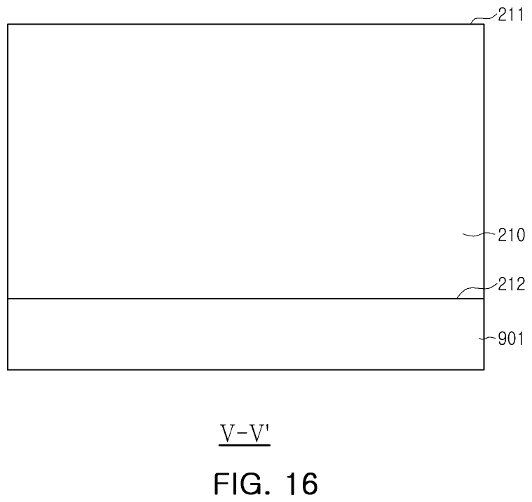

In an example embodiment, the IPO gate IPOG may have a structure, substantially the same as or similar to that of a transfer gate VTG, and may be formed using a manufacturing process, the same as or similar to that of the transfer gate VTG. Hereinafter, a process of manufacturing an image sensor according to an example embodiment of the disclosure will be described with reference to FIGS. 16 to 22.

FIGS. 16 to 22 are diagrams of a method of manufacturing the image sensor illustrated in FIG. 10.

Referring to FIG. 16, a substrate 210, including an epitaxial semiconductor layer, may be formed on a silicon substrate 901. In an example embodiment, the silicon substrate 901 may include single crystalline silicon. The substrate 210 may include a single crystalline silicon layer epitaxially grown from a surface of the silicon substrate 901. In an example embodiment, the silicon substrate 901 and the substrate 210 may include a single crystalline silicon layer doped with boron atoms B. A first surface 211 and a second surface 212, opposing the first surface 211, may be defined in the substrate 210.

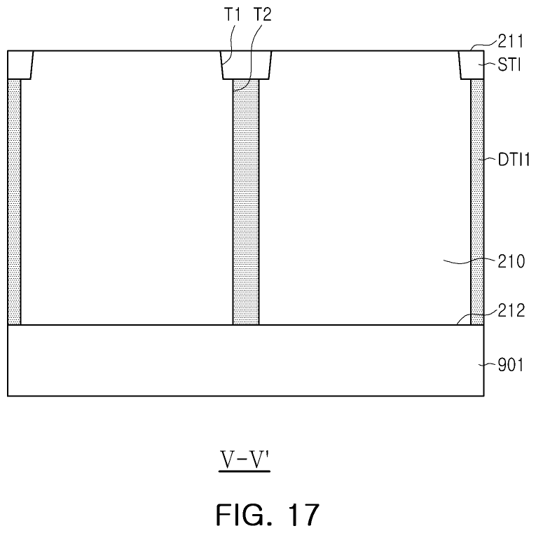

Referring to FIG. 17, a trench may be formed by partially etching the substrate 210 from the first surface 211 of the substrate 210, and an isolation pattern, filling the trench, may be formed. For example, a first trench T1 may be formed, and a device isolation pattern STI filling the first trench T1 may be formed. In addition, the substrate 210 may be etched in a position in which the device isolation pattern STI is formed, such that a second trench T2 may be formed and a first isolation pattern DTI1, filling the second trench T2, may be formed.

The second isolation pattern DTI2 is not illustrated in FIG. 17, but the second isolation pattern DTI2 may be formed using a process, the same as or similar to that of the first isolation pattern DTI1. Shared pixel regions may be defined by the first isolation pattern DTI1, and unit pixel regions of the shared pixel regions may be defined by the second isolation pattern DTI2.

In an example embodiment, after the first and second isolation patterns DTI1 and DTI2 are formed, a periphery of the first and second isolation patterns DTI1 and DTI2 may be doped with impurities using an ion implantation process.

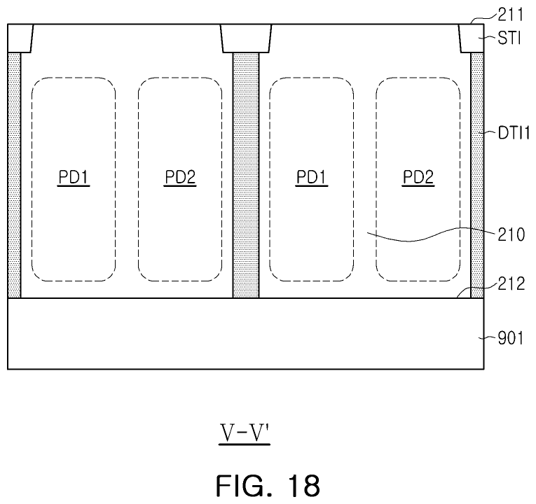

Referring to FIG. 18, a plurality of photodiodes PD1 and PD2 may be formed in a shared pixel region using an ion implantation process from the first surface 211 of the substrate 210.

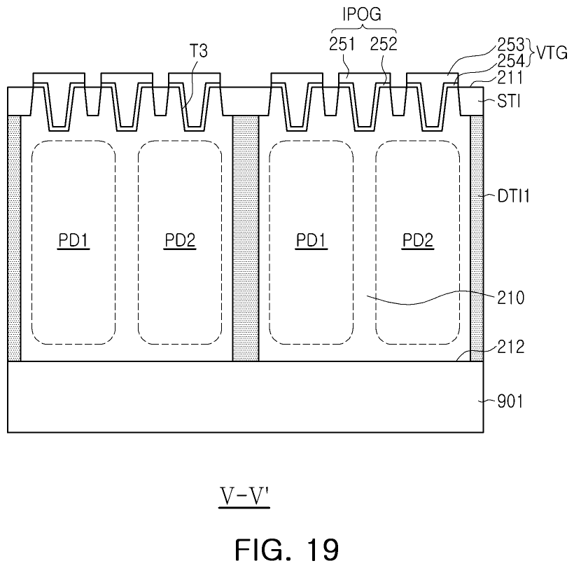

Referring to FIG. 19, a plurality of gate structures may be formed on the first surface 211 of the substrate 210. In an example embodiment, third trenches T3 may be formed by partially etching the first surface 211 of the substrate 210, gate insulating layers 252 and 254 may be formed in the third trenches T3 and peripheral regions, and gate electrodes 251 and 253 may be respectively formed on the gate insulating layers 252 and 254. The gate insulating layer 252 and the gate electrode 251 may be included in an IPO gate IPOG, and the gate insulating layer 254 and the gate electrode 253 may be included in a transfer gate VTG.

In an example embodiment, an ion implantation process may be performed on a portion of the substrate 210 to form a floating diffusion region, and a gate insulating layer and a gate electrode may be stacked on the first surface 211 of the substrate 210 to further form a plurality of transistors included in a shared pixel.

According to an example embodiment of the disclosure, the IPO gate IPOG and the transfer gate VTG may be simultaneously formed in the same manufacturing process. Accordingly, an additional manufacturing process for forming the IPO gate IPOG may not be required, and a manufacturing period and process cost may be reduced.

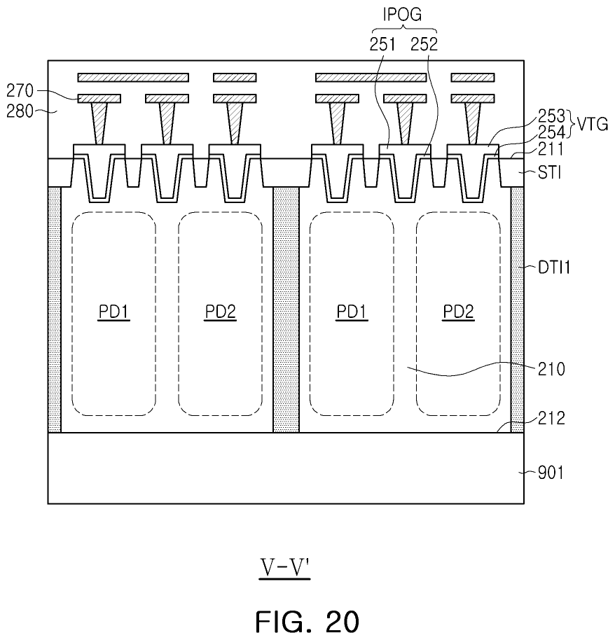

Referring to FIG. 20, conductive patterns 270 may be formed on the IPO gate IPOG, the transfer gate VTG, the plurality of transistors, and the floating diffusion region, and an insulating layer 280 covering the conductive patterns 270 may be formed, such that a pixel circuit of a shared pixel may be formed.

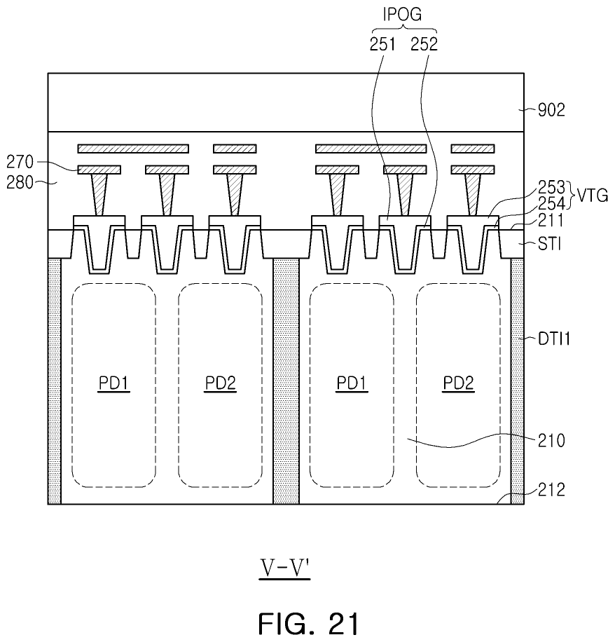

Referring to FIG. 21, a support substrate 902 may be attached to an upper portion of the insulation layer 280. When the silicon substrate 901 illustrated in FIG. 21 is removed using a mechanical grinding process, a chemical polishing (CMP) process, a wet etching process, and/or any combination thereof in a state in which the support substrate 902 is in contact with the upper portion of the insulation layer 280, the second surface 212 of the substrate 210 may be exposed.

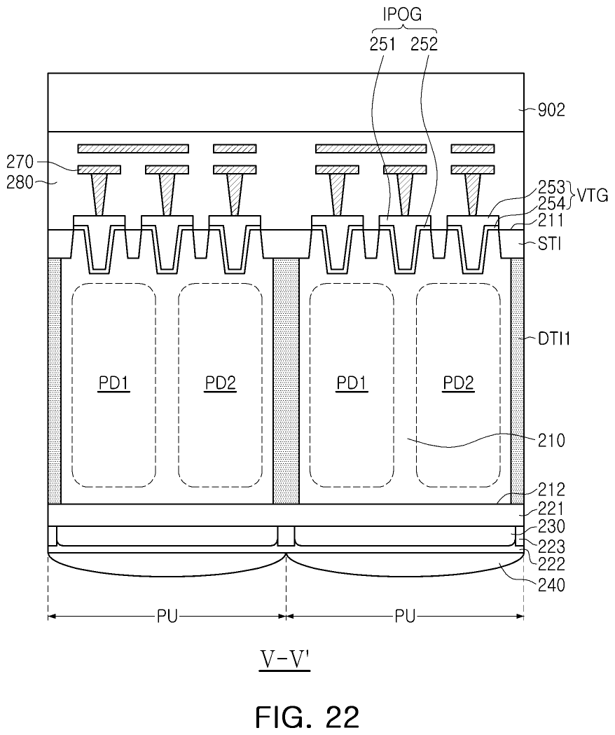

Referring to FIG. 22, a first planarization film 221, an anti-reflection film 223, a color filter 230, a second planarization film 222, and a microlens 240 may be sequentially formed on the second surface 212 of the substrate 210, such that a light transmission structure may be formed. When the support substrate 902 is removed, the image sensor 220 described with reference to FIGS. 9 and 10 may be manufactured.

A structure of an image sensor and a method of manufacturing the image sensor have been described based on a shared pixel PU of the image sensor with reference to FIG. 2 to FIG. 22, but the image sensor may further include a logic circuit 20, the same as that described with reference to FIG. 1. Hereinafter, an example structure of an image sensor including a logic circuit will be described.

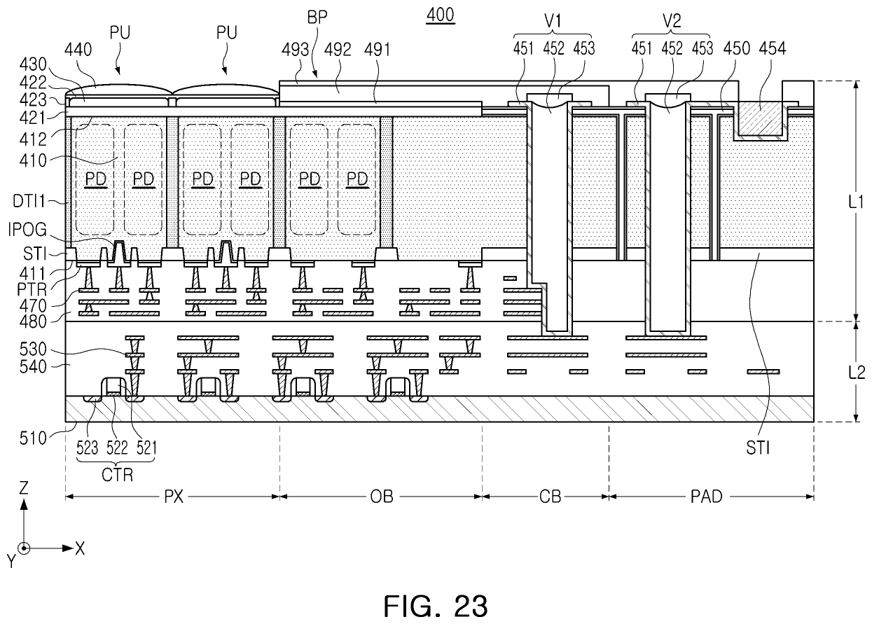

FIG. 23 is a cross-sectional view of an image sensor according to one or more example embodiments of the disclosure.

Referring to FIG. 23, an image sensor 400 may include a first semiconductor layer L1 and a second semiconductor layer L2 stacked in a third direction Z. The first semiconductor layer L1 may include a plurality of shared pixels PU, and the second semiconductor layer L2 may include a logic circuit for controlling the plurality of shared pixels PU and processing an image signal output from the plurality of shared pixels PU.

The image sensor 400 may include a pixel region PX, an optical black region OB, a connection region CB, and a pad region PAD.

In the pixel region PX, the first semiconductor layer L1 may include a substrate 410 having a first surface 411 and a second surface 412, opposing each other. A first isolation pattern DTI1 for defining a shared pixel region may be disposed in the substrate 410. A shared pixel PU may be disposed in each of shared pixel regions.

Shared pixels PU may have a structure, the same as or similar to that described with reference to FIGS. 4 to 7. For example, the shared pixels PU may include a device isolation pattern STI, a plurality of photodiodes PD, an IPO gate IPOG overlapping an IPO barrier between the plurality of photodiodes PD in the third direction Z, pixel transistors PTR, interconnection patterns 470, and an insulating layer 480. In addition, the shared pixels PU may include a first planarization film 421, an anti-reflection film 423, a color filter 430, a second planarization film 422, and a microlens 440, on the second surface 412.

The optical black region OB may be disposed to surround at least a portion of the pixel region PX. The optical black region OB may include an optical black pixel BP for use in measuring a dark current.

The first planarization film 421 of the pixel region PX may extend to the optical black region OB. The optical black region OB may further include a light-shielding conductive layer 491, a light-shielding color filter 492, and a capping layer 493, which are sequentially stacked on the first planarization film 421.

The light-shielding conductive layer 491 and the light-shielding color filter 492 may be included in a light-shielding pattern for shielding light from entering the substrate 410. In an example embodiment, the light-shielding conductive layer 491 may include a metal material. For example, the light-shielding conductive layer 491 may include at least one of tungsten (W), titanium (Ti), copper (Cu), aluminum (Al), gold (Au), silver (Ag), and an alloy thereof. For example, the light-shielding color filter 492 may include a blue (B) filter.

The capping layer 493 may be disposed on the light-shielding color filter 492. The capping layer 493 may include a material, the same as that of the microlens 440, but the disclosure is not limited thereto.

The second semiconductor layer L2 may include a substrate 510. In the pixel region PX and the optical black region OB, the second semiconductor layer L2 may include a logic circuit transistor CTR formed on an upper surface of the substrate 510, interconnection patterns 530 electrically connecting the logic circuit transistor CTR, and an insulating layer 540 covering the interconnection patterns 530. The logic circuit transistor CTR may include a gate structure 521, a gate insulating layer 522, and active regions 523.

The connection region CB may include a first via V1 for electrically connecting shared pixel circuits of the first semiconductor layer L1 and logic circuits of the second semiconductor layer L2 to each other. The first via V1 may pass through an insulating layer 450, the substrate 410, and the insulating layer 540, on the second surface 412 of the substrate 410, to be in contact with the interconnection pattern 530. The first via V1 may have a cylindrical shape. In an example embodiment, the first via V1 may have a shape having a downwardly decreasing width.

The first via V1 may include a via conductive layer 451 and a via filling layer 452. The via conductive layer 451 may include a conductive material. For example, the via conductive layer 451 may include at least one of tungsten (W), copper (Cu), aluminum (Al), gold (Au), silver (Ag), and an alloy thereof. The via filling layer 452 may be disposed on the via conductive layer 451 to fill the first connection via V1, and may have a concave upper surface. The via filling layer 452 may include an insulating material, but the disclosure is not limited thereto.

In an example embodiment, the first via V1 may further include a buffer layer 453. The buffer layer 453 may be disposed to cover an upper surface of the via filling layer 452. For example, the buffer layer 453 may include a cured photoresist material.

The pad region PAD may include a second via V2 for electrically connecting logic circuits of the second semiconductor layer L2 and an input/output pad PL of the first semiconductor layer L1 to each other. In the same manner as the first via V1, the second via V2 may pass through the insulating layer 450, the substrate 410, and the insulating layer 540, on the second surface 412 of the substrate 410, to be in contact with the interconnection pattern 530. A shape and a structure of the second via V2 may be the same as or similar to those of the first via V1.

A pad 454 may include a conductive layer on a region in which the via conductive layer 451 of the second via V2 extends. The pad 454 may be electrically connected to an external device by wire bonding or the like.

The capping layer 493 may extend from the optical black region OB, and may be disposed to cover the first via V1 and the second via V2.

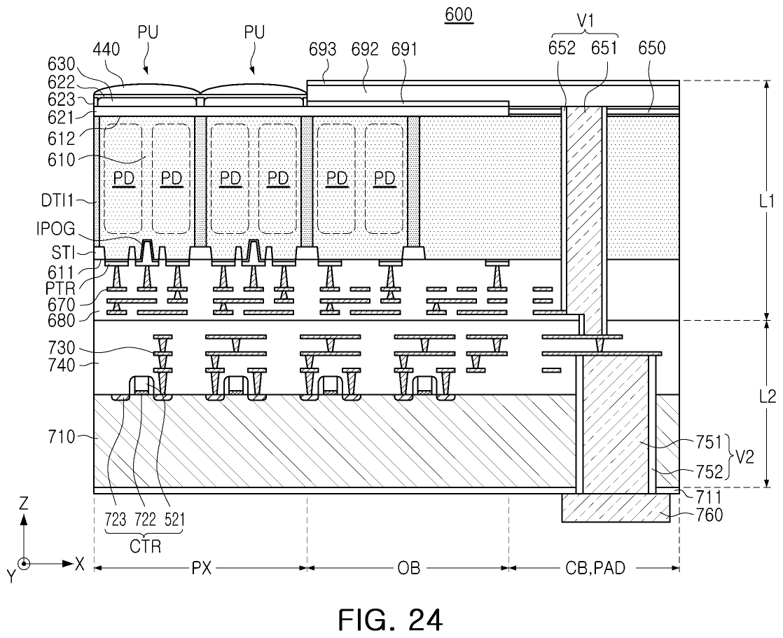

FIG. 24 is a cross-sectional view of an image sensor according to one or more example embodiments of the disclosure.

Referring to FIG. 24, an image sensor 600 may include a first semiconductor layer L1 and a second semiconductor layer L2 stacked in a third direction Z. The image sensor 600 may include a pixel region PX, an optical black region OB, a connection region CB, and a pad region PAD.

The pixel region PX and the optical black region OB of the image sensor 600 may have structures the same as or similar to those of the pixel region PX and the optical black region OB of the image sensor 400 described with reference to FIG. 24. However, structures of the connection region CB and the pad region PAD of the image sensor 600 may be different from those of the connection region CB and the pad region PAD of the image sensor 400. Hereinafter, a structure of the image sensor 600 will be described based on a difference from the image sensor 400.

In the example of FIG. 24, the connection region CB and the pad region PAD may overlap each other in the third direction Z. The connection region CB may include a first via V1 for electrically connecting shared pixel circuits of the first semiconductor layer L1 and logic circuits of the second semiconductor layer L2 to each other.

The first via V1 may extend from a first surface 612 of the substrate 610 to pass through an insulating layer 650, a substrate 610, and an insulating layer 740 to be in contact with a conductive pattern 670 of the first semiconductor layer L1 and a conductive pattern 730 of the second semiconductor layer L2. The first via V1 may have a cylindrical shape. In an example embodiment, the first via V1 may have a shape having a downwardly decreasing width.

The first via V1 may include a via conductive layer 651 and a via insulating layer 652. The via conductive layer 451 may include at least one of tungsten (W), copper (Cu), aluminum (Al), gold (Au), silver (Ag), and an alloy thereof. The via insulating layer 652 may be formed on a sidewall of a via trench, and the via conductive layer 651 may fill the via trench. The via conductive layer 651 may electrically connect the conductive pattern 670 and the conductive pattern 730 to each other.

The pad region PAD may include a second via V2 for electrically connecting logic circuits of the second semiconductor layer L2 and an input/output pad PL of the first semiconductor layer L1 to each other. The second via V2 may pass through an insulating layer 711, which is disposed on a surface of a substrate 710 that is opposite to a surface of the substrate 710 on which a logic circuit transistor CTR is formed, and pass through the substrate 710 and an insulating layer 740, to be in contact with the conductive pattern 730.

The second via V2 may include a via conductive layer 751 and a via insulating layer 752. The via insulating layer 752 may be formed on a sidewall of a via trench, and the via conductive layer 751 may fill the via trench.

An input/output pad 760 may be disposed on a lower portion of the substrate 710. The input/output pad 760 may include a conductive material such as a metal material. The input/output pad 760 may be in contact with a lower surface of the second via V2. The second via V2 may electrically connect the input/output pad 760 and the conductive pattern 730 to each other.

According to example embodiments of the disclosure, an image sensor may include an IPO gate disposed in a DTI cut region between a plurality of photodiodes included in a pixel group. The IPO gate and the plurality of photodiodes may be included in an IPO transistor, and an IPO barrier potential level may be electronically controlled according to a voltage level applied to the IPO gate.

The image sensor may control the IPO barrier potential level without modifying a pixel layout. Accordingly, a period for manufacturing an image sensor having a target IPO barrier potential level may be shortened and cost may be reduced.

According to example embodiments of the disclosure, in a method of manufacturing an image sensor, an IPO gate may be manufactured while a transfer gate included in a pixel group is manufactured, thereby shortening a period for manufacturing an image sensor capable of electronically controlling an IPO barrier potential level.

While example embodiments have been shown and described above, it will be apparent to those skilled in the art that modifications and variations could be made without departing from the scope of the disclosure as defined by the appended claims and their equivalents.

What is claimed is:

1. An image sensor comprising:
a substrate having a first surface and a second surface opposing the first surface;
a first isolation pattern defining a plurality of shared pixel regions in the substrate; and
a plurality of shared pixels respectively in the plurality of shared pixel regions,
wherein each of the plurality of shared pixels includes:
a second isolation pattern defining a plurality of unit pixel regions in a corresponding shared pixel region, the second isolation pattern having an open region in a plan view;
a plurality of photodiodes in the plurality of unit pixel regions, respectively;
a plurality of floating diffusion regions in the plurality of unit pixel regions;
the plurality of floating diffusion regions electrically connected to each other; and
an inter-pixel overflow (IPO) gate overlapping the open region in the plan view, and
wherein each of the plurality of floating diffusion regions in each of the plurality of shared pixels is spaced apart from the IPO gate in each of the plurality of shared pixels.

2. The image sensor of claim 1, wherein the second isolation pattern includes a plurality of sub-isolation patterns respectively extending from two opposite edges, among a plurality of edges of the first isolation pattern, in a direction toward a central portion of the corresponding shared pixel region, and
wherein the open region of the second isolation pattern is in the central portion of the corresponding shared pixel region.

3. The image sensor of claim 1, wherein the second isolation pattern extends from a first edge, among a plurality of edges of the first isolation pattern, in a direction toward a second edge of the first isolation pattern, the second edge opposing the first edge, and
wherein the open region is in a position adjacent to the second edge.

4. The image sensor of claim 1, wherein the plurality of floating diffusion regions in each of the plurality of shared pixels are electrically connected to each other via an interconnection pattern.

5. The image sensor of claim 1, wherein a portion of the IPO gate extends into the substrate from the first surface of the substrate.

6. The image sensor of claim 5, wherein each of the plurality of shared pixels further comprises:
a plurality of transfer gates, and
wherein a portion of each of the plurality of transfer gates extends into the substrate from the first surface of the substrate.

7. The image sensor of claim 5, wherein the open region has a first length in a first direction perpendicular to the first surface of the substrate, and
wherein the IPO gate has a second length in the first direction from the first surface of the substrate to the portion of the IPO gate extended into the substrate, and
wherein the first length is greater than the second length.

8. The image sensor of claim 5, further comprising:
a device isolation pattern on the first surface of the substrate, and
wherein the first isolation pattern is in contact with the second surface of the substrate and the device isolation pattern.

9. The image sensor of claim 1, wherein each of the second isolation pattern in each of the plurality of shared pixels is in contact with the first isolation pattern.

10. The image sensor of claim 1, wherein each of the plurality of shared pixels further comprises:
a microlens, and
wherein the plurality of photodiodes includes two photodiodes, and the two photodiodes are disposed under the microlens.

11. The image sensor of claim 1, wherein each of the plurality of shared pixels further comprises:
a microlens, and
wherein the plurality of photodiodes include four photodiodes, and the four photodiodes are disposed under the microlens.

12. The image sensor of claim 11, wherein the four photodiodes are arrange in a 2×2 matrix form in the plan view.

13. The image sensor of claim 1, wherein the IPO gate in each of the plurality of shared pixels is disposed at a center of each of the plurality of shared pixels in the plan view.

14. The image sensor of claim 1 wherein the IPO gate in each of the plurality of shared pixels is spaced apart from at a center of each of the plurality of shared pixels in the plan view.

15. An image sensor comprising:
a substrate having a first surface;
a first isolation pattern defining a plurality of shared pixel regions in the substrate; and
a plurality of shared pixels respectively in the plurality of shared pixel regions,
wherein each of the plurality of shared pixels includes:
a plurality of photodiodes included in a corresponding shared pixel region;
an inter-pixel overflow (IPO) barrier between the plurality of photodiodes in the corresponding shared pixel region; and
an IPO gate overlapping the IPO barrier in a vertical direction, which is perpendicular to the first surface.

16. The image sensor of claim 15, wherein each of the plurality of shared pixels further includes a second isolation pattern defining a plurality of unit pixel regions in the corresponding shared pixel region, the second isolation pattern having an open region, and
wherein the IPO barrier is in the open region.

17. The image sensor of claim 15, wherein a potential level of the IPO barrier is determined according to a level of a voltage applied to the IPO gate.

18. The image sensor of claim 15, wherein the IPO gate includes a first structure extending from the first surface to an inside of the substrate.

19. An image sensor comprising:
a substrate including a shared pixel region therein;
a plurality of photodiodes included in the shared pixel region; and
an inter-pixel overflow (IPO) gate extending from a surface of the substrate to a region, inside the substrate, defined between the plurality of photodiodes.

20. The image sensor of claim 19, further comprising:
a plurality of floating diffusion regions between the plurality of photodiodes and a first surface of the substrate, the plurality of floating diffusion regions electrically connected to each other;
a plurality of transfer gates respectively adjacent to the plurality of floating diffusion regions; and
a shared reset transistor, a shared source follower transistor and a shared selection transistor on the first surface.
